(19) United States
(12) Patent Application Publication
(10) Pub. No.: US 2023/0041886 A1
(43) Pub. Date: Feb. 9, 2023

(54) LIQUID COOLING SYSTEM FOR COMPUTERS

(71) Applicant: Asetek Danmark A/S, Aalborg East (DK)

(72) Inventors: Rasmus Roesen Mark, Nibe (DK); Anders Saksager, Gistrup (DK)

(73) Assignee: Asetek Danmark A/S, Aalborg East (DK)

(21) Appl. No.: 17/444,724

(22) Filed: Aug. 9, 2021

(51) Int. Cl. H05K 7/20; G06F 1/20

(52) U.S. Cl. CPC H05K 7/20272; H05K 7/20263; G06F 1/20; G06F 2200/201

(57) ABSTRACT

A system for cooling computer hardware includes a first heat exchanger and a pump. The first heat exchanger includes a computer hardware contact surface configured to be in thermal contact with the computer hardware on a first side and to be in thermal contact with a cooling liquid on a second side. The first heat exchanger also includes a liquid chamber having a pump interface with at least one chamber inlet and at least one chamber outlet. The pump includes a chamber interface with at least one pump outlet and at least one pump inlet. The pump is configured to: detachably connect at the chamber interface to the pump interface, and drive the cooling liquid from a second heat exchanger to the at least one pump outlet and from the at least one a pump inlet to the second heat exchanger.

### BACKGROUND

### Field of the Invention

Systems consistent with the present invention generally relate to a liquid cooling of a heat generating element in a computing system such as a CPU or a GPU. More particularly, systems consistent with the invention relate to the liquid cooling via a heat exchange unit and a pump unit for circulating cooling liquid.

### Discussion of the Related Art

Cooling systems for a central processing unit (CPU), a graphic processing unit (GPU) or other processing unit of a computer system are widely used to remove heat created by the processing unit.

During operation of a computer, the heat created inside the processing unit must be carried away fast and efficiently, keeping the temperature within the design range specified by the manufacturer in order to avoid heat related damage from occurring to the processing unit.

Efforts to prevent such heat related damage from occurring make use of various conventional processing unit cooling methods/systems. The most commonly used conventional cooling system utilizes an air-cooling arrangement, wherein a heat sink in thermal contact with the processing unit transports the heat away from the processing unit and either passive airflow or active airflow via a fan mounted on top of the heat sink that removes heat from the heat sink by blowing air through the segments (i.e., fins) of the heat sink.

Another conventional cooling system utilizes cooling liquid to cool the processing unit by circulating the cooling liquid inside a closed system via a pumping unit. Such a closed system also includes a heat exchanger past which the cooling liquid is circulated to allow heat to exit the system. A typical liquid-cooling system is provided as an integrated unit having both the cooling surface and the pump for circulating the cooling liquid. Liquid cooling systems have certain advantages over air-cooling arrangements. For example, a liquid-cooling system is more efficient than an air-cooling system and tends to generate less noise. These advantages are making liquid cooling systems more and more popular especially given that increased cooling demands are occurring as the size and performance of processing units continue to increase (which also increases the heat generated from such processing units).

However, the increased demand for liquid cooling arrangements has brought to light certain disadvantages of conventional liquid cooling systems. For example, since conventional liquid cooling systems are designed to accommodate very specific processor configurations, multiple different types of liquid cooling systems must be created to accommodate different processing units because the size of different processing units (and consequently the heat generated by such processing units) vary over a wide range. Since multiple different liquid cooling systems with different capacities and varying sizes are necessary to provide efficient cooling to the different processing units under conventional designs, (i) consumers are forced purchase entirely new liquid cooling systems when their processor configurations change, and (ii) the cost of such systems remain high since manufacturers are unable to achieve necessary economies of scale due to the fact that any particular liquid cooling system will only be compatible with a fraction of processor configurations.

In view of the foregoing, it is desirable to reduce the need for replacing liquid cooling systems and to lower the manufacturing costs of liquid cooling systems. For example, there is a need for an improved method and system to provide liquid cooling to consumers in a manner that is less likely to need replacement as and that will cost less.

### SUMMARY OF THE INVENTION

In contrast to the above described conventional liquid cooling systems, an improved system is flexible and easy to adapt to processing units of varying sizes by providing a single heat exchanger that can interface and easily connect/disconnect from cooling fluid pumps of various power levels. The power level of a chosen cooling fluid pump can be matched to the heat dissipation needs of a given processing unit. This level of customization (i) provides consumers the flexibility to apply the cooling system to a wider variety of computer configurations, (ii) simplifies the manufacturing process by limiting manufacturing tooling recourses to a single heat exchanger design (and thus lowers costs via optimizing economies of scale). Additionally, the improved cooling system can be easily detached from processing units and reused on other processing units. This allows consumers to avoid having to purchase an additional liquid cooling system when they decide to upgrade from one computer configuration to another.

A system for cooling computer hardware includes a first heat exchanger including: a computer hardware contact surface configured to be in thermal contact with the computer hardware on a first side and to be in thermal contact with a cooling liquid on a second side, the second side being opposite to the first side, and a liquid chamber having a pump interface with at least one chamber inlet and at least one chamber outlet, the liquid chamber being configured to (i) direct the cooling liquid to enter from the at least one chamber inlet, (ii) traverse along the second side of the contact surface, and (iii) exit from the at least one chamber outlet; and a pump having a chamber interface with at least one pump outlet and at least one pump inlet, the pump being configured to: detachably connect at the chamber interface to the pump interface of the first heat exchanger, and drive the cooling liquid (i) from a second heat exchanger to the at least one pump outlet and (ii) from the at least one a pump inlet to the second heat exchanger; wherein, when the chamber interface is connected to the pump interface, the at least one chamber outlet is in sealed fluid connection with the at least one pump inlet and the at least one chamber inlet is in sealed fluid connection with the at least one pump outlet.

A heat exchanger for dissipating heat from computer hardware includes a computer hardware contact surface configured to be in thermal contact with the computer hardware on a first side and to be in thermal contact with a cooling liquid on a second side, the second side being opposite to the first side, and a liquid chamber having a pump interface with at least one chamber inlet and at least one chamber outlet, the liquid chamber being configured to (i) direct the cooling liquid to enter from the at least one chamber inlet, (ii) traverse along the second side of the contact surface, and (iii) exit from the at least one chamber outlet; wherein the heat exchanger is configured to detachably connect at the pump interface to a chamber interface of a pump, the pump interface including at least one pump outlet and at least one pump inlet; wherein the pump is configured to drive the cooling liquid (i) from a cooling device to the at least one pump outlet and (ii) from the at least one a pump inlet to the cooling device; wherein, when the chamber interface is connected to the pump interface, the at least one chamber outlet is in sealed fluid connection with the at least one pump inlet and the at least one chamber inlet is in sealed fluid connection with the at least one pump outlet.

### BRIEF DESCRIPTION OF THE DRAWINGS

The accompanying drawings, which are incorporated in and constitute a part of this disclosure, illustrate various embodiments and aspects of the present invention. In the drawings:

FIG. 1 is a perspective view of a liquid cooling system in accordance with a first embodiment of the invention;

FIG. 2 is a perspective view of the heat exchanger of the liquid cooling system of FIG. 1; and

FIG. 3 is an internal view of the pump of the liquid cooling system of FIG. 1.

### DETAILED DESCRIPTION

The following detailed description refers to the accompanying drawings. Wherever possible, the same reference numbers are used in the drawings and in the following description to refer to the same or similar parts. While several exemplary embodiments and features of the invention are described herein, modifications, adaptations, and other implementations are possible without departing from the spirit and scope of the invention. For example, substitutions, additions, or modifications may be made to the components illustrated in the drawings, and the exemplary methods described herein may be modified by substituting, reordering, or adding steps to the disclosed methods. Accordingly, the following detailed description does not limit the invention. Instead, the proper scope of the invention is defined by the appended claims.

Systems and methods consistent with the invention generally relate to a liquid cooling of a heat generating element in a computing system such as a CPU or a GPU.

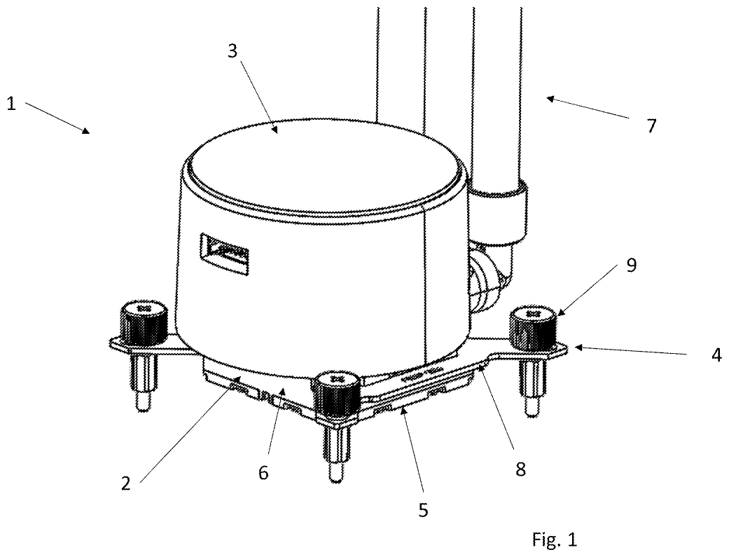

FIG. 1 illustrates an embodiment of the liquid cooling system 1 according to the invention. The liquid cooling system 1 includes a heat exchange unit 2 and a pump unit 3.

The heat generating element is an element which generates heat during operation and is typically mounted in the motherboard or mainboard of a computing system. In this context, the heat generating element may include more than the CPU or GPU itself, and may also include neighbouring areas (e.g., attachments). One surface of the heat generating element (i.e., an exposed surface) is in contact with a cooling surface 5 of the cooling system 1 and this exposed surface is denoted as the upper surface of the heat generating element.

The heat exchange unit 2 is the unit in contact with the heat generating element and has a cooling surface 5 which is cooled by cooling liquid. Although it is denoted as a surface, the cooling surface 5 is a plate-like member or a cooling plate 5 with two opposite surfaces (i.e. a surface facing the cooling liquid in a chamber 6 and an opposite surface facing the upper surface of the heat generating element). The cooling surface 5 is preferably made from a material with good heat conducting properties such as metal (e.g. copper). The cooling liquid is circulated in the chamber 6 and contacts the cooling plate 5 via at least one chamber inlet 21 and the at least on chamber outlet 23.

The pump unit 3 comprises a pump 30 connected with the tube system 7 and includes the at least one pump outlet 31 and at least one pump inlet 33. The at least one pump outlet 31 is adapted for connection with the chamber inlet 21 of the heat exchange unit 2, and, in a similar manner, the at least one pump inlet 33 is adapted for connection with the chamber outlet 23 of the heat exchange unit 2.

Consequently, the heat exchange unit 2 is connected with the pump unit 3 via a chamber connecting interface (on the pump unit 3) and the pump connecting interface (on the heat exchange unit 2) such that the at least one pump outlet 31 is connected with the at least one chamber inlet 21 and the at least one pump inlet 33 is connected with the chamber outlet 31. Thus, cooling liquid can be circulated in the chamber 6 of the heat exchange unit 2 via the pump 30 in the pump unit 3.

The heat exchange unit 2 and the pump unit 3 are interconnected by contacting the pump connecting interface of the heat exchange unit 2 with the chamber connecting interface of the pump unit 3.

To obtain an interconnection where there is alignment between the positions of the at least on pump outlet 31 and the at least one chamber inlet 21 and alignment between the positions of the at least one pump inlet 33 and the chamber outlet 23, the pump connecting interface of the heat exchange unit 2 are preferably connected with the chamber connecting interface of the pump unit 3 by means of guiding devices 20.

Although, the guiding devices 20 may be external guiding devices it is preferable that the guiding devices 20 are integrated in the heat exchange unit 2 and/or the pump unit 3. Thus, in the embodiment as depicted in FIG. 1, the invention relates to a liquid cooling system 1 wherein the heat exchange unit 2 and/or the pump unit 3 comprises guiding devices 20 for guiding the pump connecting interface and the chamber connecting interface into contact. The heat exchange unit 2 and/or the pump unit 3 may comprise one or more guiding devices 20. Preferably the guiding devices 20 are visible during connection of the heat exchange unit 2 with the pump unit 3 as this will facilitate the connection.

The guiding devices 20 preferably include physical measures and in an embodiment of the liquid cooling system the one or more guiding devices 20 may be a tap, a projection, a recess, a rail, a rim, a groove, etc. Moreover, the one or more guiding devices 20 may serve to attach the pump connecting interface to the chamber connecting interface, and in this respect to attach the heat exchange unit 2 to the pump unit 3. attachment can be via mechanical attachment devices, such as screws, bolts, clips, clamps, snap-fit connections, attachment devices which can engage by squeezing, etc.

The chamber inlet 21 and the chamber outlet 23 may include a protrusion forming a rim which can engage with the pump outlet 31 and the pump inlet 33 such that fluid-tight connections can be established. The connections may also include packings to ensure the tightness such that a sealed connection is obtained between respectively the chamber inlet 21 and the pump outlet 31 and the chamber outlet 23 and the pump inlet 33.

In one embodiment, the interconnection between the heat exchange unit 2 and the pump unit 3 is releasable, such that the heat exchange unit 2 and the pump unit 3 easily can be disconnected from each other. In this manner, it is possible to, for example, replace the pump unit 3 with a more powerful one if larger pumping capacity is required. Generally, this embodiment provides flexibility to the system as the parts, such as a specific heat exchange unit 2 or specific pump unit 3 easily can be replaced with another part.

In one embodiment, the tube system 7 in the pump unit 3 connects the pump 30 with a cooling device (e.g., another heat exchanger), such that cooling liquid from the chamber 6 in the heat exchange unit 2 via the pump 30 in the pump unit 3 can be transported to the cooling device. In the cooling device, the cooling liquid is cooled before it is pumped back to the chamber 6 in the heat exchange device 2. The cooling device may include one or more electric operated fans, such cooling devices are generally well-known in the technical field of computer hardware.

In one embodiment of the liquid cooling system 1, the cooling device is integrated in the pump unit 3 such the cooling device forms part of the pump unit 3. In an alternative embodiment the cooling device is an external device, and the pump unit 3 is connected with the cooling device via tubes 7 outside the pump unit. In this embodiment the cooling device may serve to cool liquid from other systems than the liquid cooling system 1 of the invention.

In one embodiment of the liquid cooling system 1, the thermal contact between the cooling surface of the exchange unit and the upper surface of the heat generating element is established by clamps. In this manner an efficient contact and cooling between the cooling surface and the upper surface of the heat generating element can be achieved.

The parts in the pump unit 3 and the heat exchange unit 2 can be made from any suitable material, such as plastic, polymer, ceramics or metallic materials. Preferably these parts are made from plastic or polymer material. In the heat exchange unit 2, the chamber 6 for cooling liquid is preferably made from plastic or polymer material and the cooling surface 5 is preferably made from a material with good heat conductive properties, such as metal (e.g., copper).

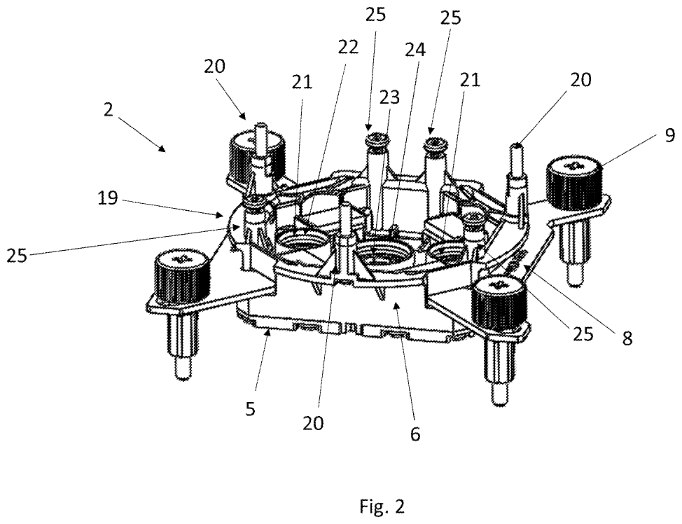

FIG. 2 illustrates the exchange unit 2 with the cooling surface 5 and chamber 6. The pump unit 3 is not present in FIG. 2. However, the support 19 where the exchange unit 2 engages the pump unit 3 is visible in FIG. 2. FIG. 2 also shows the guiding devices 20 to guide the pump unit 3 into the correct position. In this embodiment the guiding devices 20 are shaped as tabs or as pillars. It is preferred that the guiding devices 20 are visible during assembling of the cooling system 1 as this will facilitate the assembling of the heat exchange unit 2 and the pump unit 3.

Moreover, FIG. 2 also shows two chamber inlets 21 and a central chamber outlet 23 in the upper and central portion of the of the chamber 6. The chamber inlets 21 are adapted to engage with pump outlets in the pump unit and the chamber inlets 21 comprise protruding rims 22 with packings for fluid-tight engagement with the pump outlets. The chamber outlet 23 placed in the centre of the chamber 6 also comprises a protruding rim 24 with a packing for fluid-tight engagement with the pump inlet. The solution with two separate chamber inlets 21 and a central outlet 23 (with larger diameter) provides an excellent circulation of cooling liquid in the chamber 6. An alternative solution with two separate outlets and a central inlet will also work very well.

As seen in FIG. 2, the exchange unit 2 may also include guiding/attaching devices 25, which may also serve as guiding devices and furthermore for attachment of the pump unit 3 to the heat exchange unit 2.

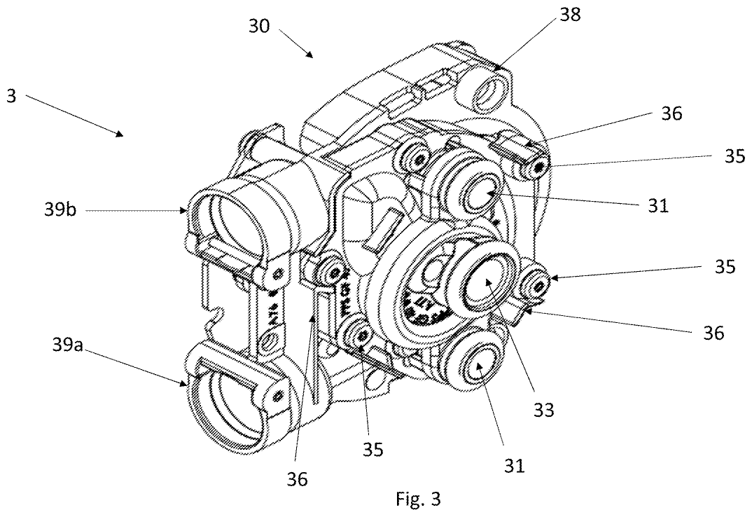

FIG. 3 illustrates the pump 30 of the pump unit 3 without the external housing. The pump 30 is mounted on the heat exchange unit 2 and cooperates with the heat exchange unit 2 by delivering cooling liquid to the chamber 6, thereby allowing the cooling surface 5 to cool a heat generating surface.

In FIG. 3, the connection 39a and 39b for the tubes 7 with the pump 30 is seen. The tubes transport cooling liquid between the pump 30 and an external cooling device.

As seen in FIG. 3, the guiding devices 20 can engage with guiding plates 36 on the pump 30 such that the pump 30 can be correctly mounted with respect to the heat exchange unit 2.

As seen in FIG. 3, the pump 30 includes two pump outlets 31 which can engage with the chamber inlets 21 on the heat exchange unit 2. The pump 30 also includes a pump inlet 33 for engagement with the chamber outlet 23 of the heat exchange device 2. The pump outlets 31 and the pump inlet 33 have a protrusion which can engage with the rims 22 of the chamber inlets 21 and the rim 24 of the chamber outlet 23. The engagement of the protrusions and the rims 22, 24 also serves as a guiding mechanism between the heat exchange unit 2 and the pump unit 3.

The pump unit 30 also include fasteners 35, 38 for attachment to the exchange unit. These fasteners 35, 38 may include at least one of a screw, a clamp, a bolt, and a snap-fit connector. When the heat exchange unit 2 and the pump unit 3 are assembled and attached to each other, a fluid-tight connection is established between the two units 2, 3.

The pump connecting interface of the heat exchange unit 2 is the surface comprising the chamber inlets 21 and the chamber outlet 23 (i.e., the surface opposite the cooling plate 5). In a similar manner the chamber connecting interface of the pump 30 is the surface comprising the pump outlets 31 and the pump inlet 33.

The foregoing description has been presented for purposes of illustration. It is not exhaustive and does not limit the invention to the precise forms or embodiments disclosed. Modifications and adaptations of the invention will be apparent to those skilled in the art from consideration of the specification and practice of the disclosed embodiments of the invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system for cooling computer hardware comprising:
a first heat exchanger including:
a computer hardware contact surface configured to be in thermal contact with the computer hardware on a first side and to be in thermal contact with a cooling liquid on a second side, the second side being opposite to the first side, and
a liquid chamber having a pump interface with at least one chamber inlet and at least one chamber outlet, the liquid chamber being configured to (i) direct the cooling liquid to enter from the at least one chamber inlet, (ii) traverse along the second side of the contact surface, and (iii) exit from the at least one chamber outlet; and
a pump having a chamber interface with at least one pump outlet and at least one pump inlet, the pump being configured to:
detachably connect at the chamber interface to the pump interface of the first heat exchanger, and
drive the cooling liquid (i) from a second heat exchanger to the at least one pump outlet and (ii) from the at least one a pump inlet to the second heat exchanger;
wherein, when the chamber interface is connected to the pump interface, the at least one chamber outlet is in sealed fluid connection with the at least one pump inlet and the at least one chamber inlet is in sealed fluid connection with the at least one pump outlet.

2. The system of claim 1:
wherein the first heat exchanger includes at least one first guide;
wherein the pump includes at least one second guide configured to mate with the at least one first guide;
wherein, when the at least one second guide mates with the at least one first guide, the at least one chamber outlet is aligned with the at least one pump inlet and the at least one chamber inlet is aligned with the at least one pump outlet.

3. The system of claim 2, wherein the first guide and the second guide are a guide rail insert and a guide rail.

4. The system of claim 2, wherein the first guide and the second guide are a projection and a recess.

5. The system of claim 2, wherein the first guide and the second guide are an outer rim and an inner rim.

6. The system of claim 2 wherein the pump being configured to detachably connect at the chamber interface to the pump interface of the heat exchanger is accomplished by detachable connection between the first guide and the second guide.

7. The system of claim 6 wherein the detachable connection includes at least one of a screw, a clamp, a bolt, and a snap-fit connector.

8. The system of claim 2 wherein the pump being configured to detachably connect at the chamber interface to the pump interface of the heat exchanger is accomplished by detachable connection remote from the first guide and the second guide.

9. The system of claim 8 wherein the detachable connection includes at least one of a screw, a clamp, a bolt, and a snap-fit connector.

10. The system of claim 1, wherein the pump being configured to detachably connect at the chamber interface to the pump interface of the heat exchanger includes the use of at least one of a screw, a clamp, a bolt, and a snap-fit connector.

11. The system of claim 1 wherein the at least one chamber outlet is a first and second radial outlet and the at least one chamber inlet is a central inlet.

12. The system of claim 1 wherein the at least one chamber inlet is a first and second radial inlet and the at least one chamber outlet is a central outlet.

13. The system of claim 1 wherein the second heat exchanger is integrated into the pump.

14. The system of claim 1, wherein the second heat exchanger is separate from the pump and is disposed in fluid communication with the pump via tubes.

15. The system of claim 1, wherein the second heat exchanger is a cooling device configured to transfer heat from the cooling fluid to an external environment.

16. The system of claim 1, wherein the computer hardware contact surface of the first heat exchanger is configured to detachably connect to the computer hardware.

17. The system of claim 16, wherein the computer hardware contact surface of the first heat exchanger being configured to detachably connect to the computer hardware includes the use of at least one of a screw, a clamp, a bolt, and a snap-fit connector.

18. A heat exchanger for dissipating heat from computer hardware, the heat exchanger comprising:
a computer hardware contact surface configured to be in thermal contact with the computer hardware on a first side and to be in thermal contact with a cooling liquid on a second side, the second side being opposite to the first side, and
a liquid chamber having a pump interface with at least one chamber inlet and at least one chamber outlet, the liquid chamber being configured to (i) direct the cooling liquid to enter from the at least one chamber inlet, (ii) traverse along the second side of the contact surface, and (iii) exit from the at least one chamber outlet;
wherein the heat exchanger is configured to detachably connect at the pump interface to a chamber interface of a pump, the pump interface including at least one pump outlet and at least one pump inlet;
wherein the pump is configured to drive the cooling liquid (i) from a cooling device to the at least one pump outlet and (ii) from the at least one a pump inlet to the cooling device;
wherein, when the chamber interface is connected to the pump interface, the at least one chamber outlet is in sealed fluid connection with the at least one pump inlet and the at least one chamber inlet is in sealed fluid connection with the at least one pump outlet.

19. The heat exchanger of claim 18:
further comprising at least one first guide configured to mate with at least one second guide;
wherein the pump includes at the least one second guide;
wherein, when the at least one first guide mates with the at least one second guide, the at least one chamber outlet is aligned with the at least one pump inlet and the at least one chamber inlet is aligned with the at least one pump outlet.

20. The heat exchanger of claim 18,
wherein the heat exchanger being configured to detachably connect at the pump interface to the chamber interface of the pump includes the use of at least one of a first screw, a first clamp, a first bolt, and a first snap-fit connector;
wherein the computer hardware contact surface is configured to detachably connect to the computer hardware via the use of at least one of a second screw, a second clamp, a second bolt, and a second snap-fit connector.
